(19) United States
(12) Patent Application Publication
(10) Pub. No.: US 2021/0090981 A1
(43) Pub. Date: Mar. 25, 2021

(54) SURFACE FINISH SURROUNDING A PAD

(71) Applicant: Intel Corporation, Santa Clara, CA (US)

(72) Inventor: Praneeth AKKINEPALLY, Tempe, AZ (US)

(21) Appl. No.: 16/578,704

(22) Filed: Sep. 23, 2019

(51) Int. Cl. H01L 23/498; H01L 21/48

(52) U.S. Cl. CPC H01L 23/49811; H01L 21/4853; H01L 23/49827

(57) ABSTRACT

Embodiments of the present disclosure may generally relate to systems, apparatus, and/or processes directed to a manufacturing process flow for a pad that is substantially surrounded by a surface finish such as ENEPIG. Embodiments may be directed to a pad that has a first side and a second side opposite the first side, a VIA that has a first end and a second end, where the first end of the VIA is coupled with at least a portion of the first side of the pad, and a surface finish directly coupled with and surrounding a surface of the pad that excludes the at least the portion of the first side of the pad.

### FIELD

Embodiments of the present disclosure generally relate to the field of package assemblies, and in particular, package assemblies that include surface finishes such as electroless nickel electroless palladium immersion gold (ENEPIG).

### BACKGROUND

Continued reduction in end product size of mobile electronic devices such as smart phones and ultrabooks is a driving force for the development of reduced size system in package components.

### BRIEF DESCRIPTION OF THE DRAWINGS

FIG. 1 illustrates an example legacy package assembly that has a surface finish on top of pads at a first level interconnect (FLI) and a second level interconnect (SLI) of the package.

FIG. 2 illustrates an example package assembly that has a surface finish surrounding pads at a FLI and SLI of the package, in accordance with embodiments.

FIGS. 3A-3L illustrate an example of a package assembly that includes a surface finish surrounding one or more pads at various stages of the manufacturing process, in accordance with embodiments.

FIGS. 4A-4W illustrate an example of a package assembly that includes a surface finish surrounding one or more pads at various stages of the manufacturing process that uses a lithography vertical interconnect access (VIA) (LIV) technique, in accordance with embodiments.

FIG. 5 illustrates an example of a process to surround a pad that is part of a package assembly with surface finish, in accordance with embodiments.

FIG. 6 schematically illustrates a computing device, in accordance with embodiments.

### DETAILED DESCRIPTION

Embodiments of the present disclosure may generally relate to systems, apparatus, and/or processes directed to a manufacturing process flow for a pad that is substantially surrounded by a surface finish such as ENEPIG. Embodiments may be directed to a pad that has a surface finish directly coupled with and surrounding a surface of the pad.

For packages, an FLI on the package may provide a source of one or more high-stress joints that may become a vulnerable interconnect for the package. With respect to electrical conductivity, a surface finish that is used to protect the pad underneath the FLI is important to forming a reliable joint connection. In legacy flip-chip packages that may typically have a bump pitch greater than 100 micrometers (μm), for example, a micro-ball that may include a tin-based solder, ENEPIG is typically used as a surface finish. This may be true not only for the FLI joints but also for SLI joints and other bonding of passive devices such as die side capacitors (DSC).

As package architectures incorporate tighter bump pitches, an ENEPIG surface finish on a pad could become detrimental to the package reliability due to the number of metal interfaces (e.g. intermetallic compounds) that are formed from placing the surface finish on a pad. For example, with tighter bump pitches, a FLI may use plated FLI using copper or tin instead of incorporating a micro-ball. For plated FLI, surface finish may become redundant and detrimental. The resulting metal interfaces may pose a risk of cracks due to interfacial stress. To address this, embodiments described herein may be directed to implementing a surface finish not on all pads, limited to SLI pads and/or DSC pads, and to not include surface finish on all FLI pads to reduce the risk of interfacial stress points. Other embodiments described herein may be directed to applying a surface finish selectively on a subset of pads in the package. This may be referred to as a selective surface finish (SSF) approach. Embodiments described herein may be directed to applying surface finish substantially around the surface of the pad, in contrast to legacy approaches that apply surface finish to just a portion of a top side of the pad.

In legacy implementations, surface finish may be applied to pads selectively to a subset of pads in a package by selectively opening solder resist (SR) on top of DSC and SLI pads only using photo-lithography, and then performing a surface finish application to the exposed portions of those pads. The rest of the FLI pads may be opened later, for example through laser ablation. However, this legacy process includes disadvantages such as capital costs and decreased package manufacturing throughput. For example, only an exposed portion of a pad may be applied with a surface finish, rather than applying the surface finish over the entire surface of the pad or substantially the entire surface of the pad. In addition, these disadvantages may multiply with respect to future packages where the number of VIAs expected to be drilled increases rapidly, or even exponentially, requiring many more pads to be coupled with the VIAs. Additionally, these legacy processes also limit use of types of SR as the selected SR must be compatible with laser drilling and VIA cleaning processes.

Embodiments described herein provide more versatile package assembly options while providing higher quality surface finishing. For example, the process of surface layer dielectric opening may use either laser drilled or photo-defined processes while applying the surface finish to selected pads instead of applying only laser drilling techniques. In addition, embodiments may provide more versatility because the surface finish technique may be completed before dielectric lamination. Thus, embodiments may apply to a wider range of dielectric materials in the package manufacturing process.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

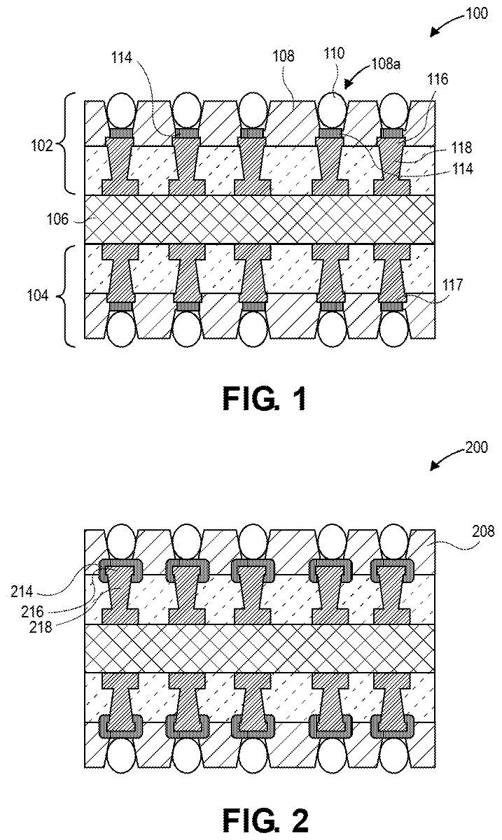

FIG. 1 illustrates an example legacy package assembly that has a surface finish on top of pads at a FLI and a SLI of the package. Diagram 100 includes a package with two sides that include an FLI side 102 and a SLI side 104 that may be separated by a substrate core 106. The FLI side 102 includes a dielectric material 108 that may include but is not limited to photo-definable dielectric, non-photo-definable dielectric, an insulator, and/or a mold. The dielectric material 108 may include one or more openings 108a, which may also be referred to as cavities, into which a solder ball 110 may be inserted. The openings 108a may be created using laser or mechanical drilling, or photolithography. In the bottom of the openings 108a there may be an ENEPIG surface finish 114. The ENEPIG surface finish 114 may include multiple layers of gold, nickel, and palladium. The ENEPIG surface finish 114 electrically couples to an FLI surface pad 116 that is connected to a VIA 118. As a result, the ENEPIG surface finish 114 may only cover a portion of a top of the surface pad 116. In embodiments, the ENEPIG surface finish 114 may be made of another element, material, or compound in place of ENEPIG.

Legacy processes for creating this package include selectively opening cavities 108a on top of DSC and FLI pads 116 only using photolithography processes and applying the ENEPIG surface finish 114 to those pads. Other FLI pads 116 may be opened later through laser ablation. However, this approach has limitations that include high process and capital cost, slow throughput, and limitation in the types of surface layer dielectric that may be used. High process and capital cost may also result due to FLI locations, openings 108a, being opened using laser drill as opposed to conventional photolithography. The cost incurred to drill all the SROs is expected to be high. Additionally, since the solder resist/solder mask, which may correspond to dielectric material 108, is typically photo-defined the laser drill requires new equipment installation resulting in higher capital cost. SLI pads 117 may be created in a fashion similar to the FLI pads 116 described above.

In legacy implementations, slower throughput may result because the laser drill process to create cavity 108a is much slower than a photo-lithography process. With respect to limitations in the surface layer dielectric, because the surface layer dielectric material 108, is now laser drilled, the dielectric material 108 needs to be compatible with laser drill, VIA cleaning and other processes that are typically used in the inner layers of the package 100. As a result, this restricts the ability to use conventional solder resist materials for the dielectric material 108 that are not completely laser compatible, for example with respect to absorbance in laser wavelength, VIA residue amount, and the like.

FIG. 2 illustrates an example package assembly that has a surface finish surrounding pads at a FLI and SLI of the package, in accordance with embodiments. Diagram 200 shows a package that may be similar to diagram 100, however the ENEPIG surface finish 214 wraps around the pad 216, and covers more than just a portion of a top surface of the pad. In embodiments, the ENEPIG surface finish 214 may cover all areas of the pad 216 except for the areas where the pad 216 is connected to the VIA 218. In embodiments described further below, the ENEPIG surface finish 214 may be applied before the dielectric material 208, which may be similar to dielectric material 108 of FIG. 1, is applied or laminated. In embodiments, this is accomplished by plating the pads 216 that require the ENEPIG surface finish 214 first, then subsequently applying one or more legacy procedures to complete the package 200. In addition, electrochemical displacement may be used to apply the ENEPIG surface finish 214 to the pads 216 first without a dielectric material 208 in place.

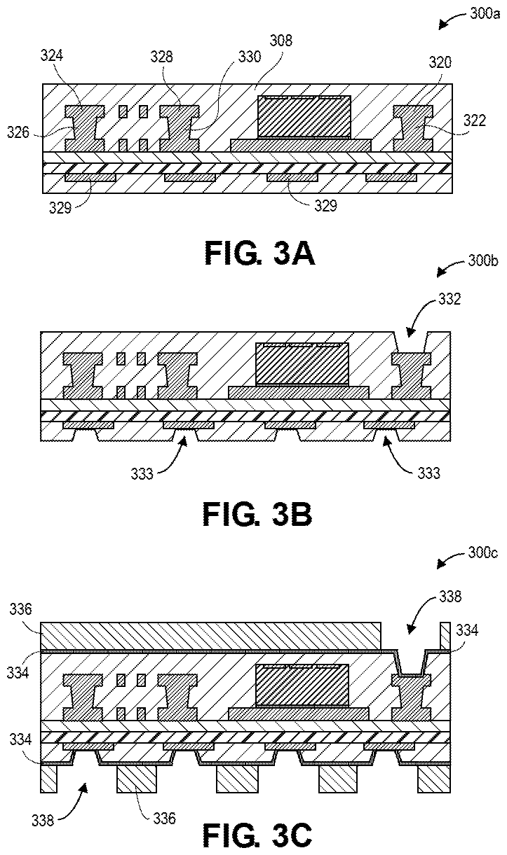

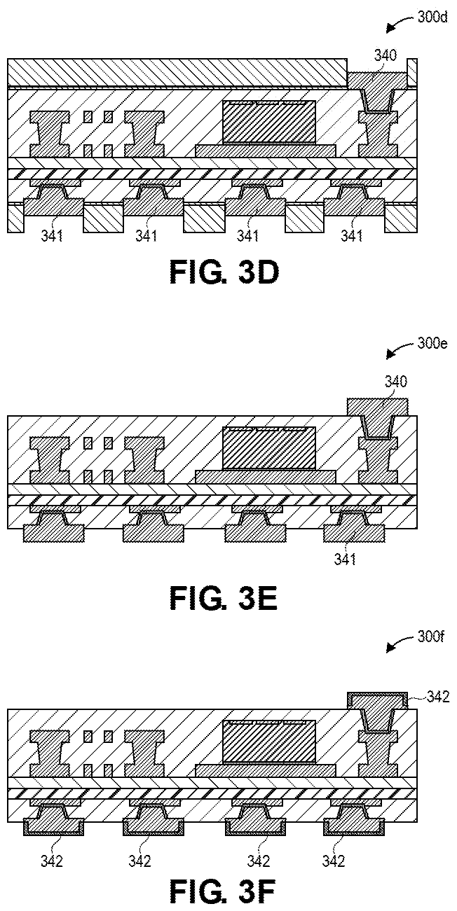

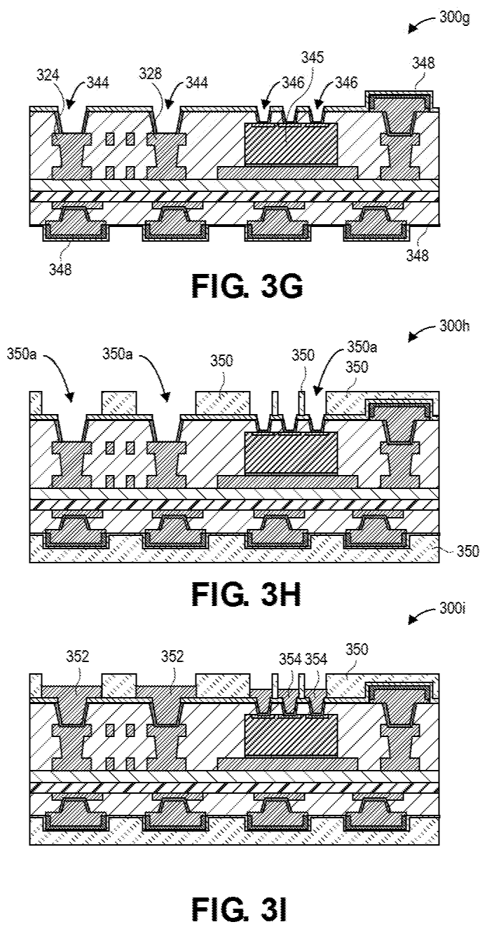

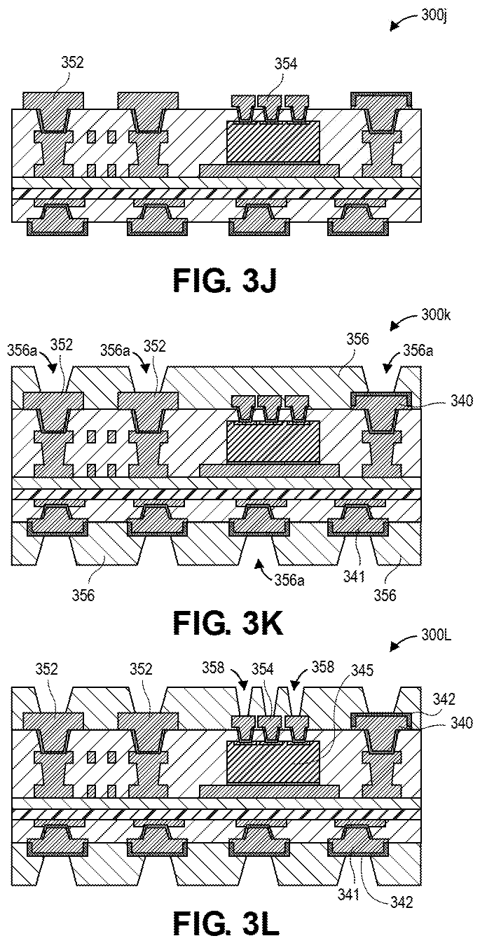

FIGS. 3A-3L illustrate an example of a package assembly that includes a surface finish surrounding one or more pads at various stages of the manufacturing process, in accordance with embodiments. FIGS. 3A-3L shows an embodiment of a process flow of an embedded multi-die interconnect bridge (EMIB)® architecture using a photo-definable SR. Other embodiments may include other architectures such as conventional substrate packaging, substrate packaging using non-photo definable dielectric, EMIB architectures using lithography VIA (LIV)-based approach for surface VIA formation, etc. The process starts with a substrate built to the N-1 layer. The substrate is then selectively drilled, cleaned and desmeared with a protective film and patterned to form the pads that will require surface finish, for example DSC pads and SLI pads. After the pads are plated, a seed layer is etched off and the remnant palladium (Pd) is stripped off by using, for example, potassium cyanide (KCN) chemistry or some other suitable chemistry.

Subsequently, pads are processed through ENEPIG which results in a nickel (Ni)-Pd-gold (Au) surface formation around the pad due to autocatalytic reaction. This may also be referred to as electrochemical displacement, where one metal is displaced by another metal. As a result, copper pads 216 of FIG. 2 are covered, or plated, with ENEPIG surface finish 214 all around and the ENEPIG surface finish 214 is not formed at other locations, for example between copper pads 216. After the surface finish process, the rest of the pattern may be formed by conventional laser drill, desmear and patterning. This results in the selective surface finish of the pads as required, both DSC and/or SLI. In embodiments, the backside surface finish is protected with film options which include but are not limited to PolyEthylene Teraphthalate (PET), PE PolyEthylene (PE), PolyEthylene Naphthalate (PEN) and/or Nylon with an adhesive.

After the rest of the surface is patterned, the surface dielectric is laminated and photo-defined to form a first set of solder resist openings (SRO) and laser drilled to form a second set of SRO for a tighter bump pitch. In embodiments, the first set of SRO and the second set of SRO may be different sized SROs. The substrate may then be processed using conventional back-end process flow.

FIG. 3A shows a package 300a as a substrate built up to an N-1 layer, or surface—1 layer. The package 300a may include FLI pads 324, 328, 320 that are coupled respectively with VIAs 326, 330, 322. The package 300a may also include SLI pads 329, and may be enclosed by or partially enclosed by a molding 308.

FIG. 3B shows the package 300b at an assembly stage where cavities 332, 333 have been created into the package 300b to expose pads 320, 329 respectively. In embodiments, this may be accomplished with a CO₂ VIA drill and desmear with a protective film applied on the front side and the backside of the package 300b. In embodiments, the front side may correspond to the FLI side and the back side correspond to a SLI side.

FIG. 3C shows the package 300c at an assembly stage where a seed layer 334 is applied to both sides of the package 300c. This may be accomplished through an electroless plating process, a sputter process, or some other suitable process. Subsequently, a dry film resist (DFR) lamination 336 may be applied. Openings 338 may subsequently be created through the DFR lamination 336 to expose portions of the seed layer 334.

FIG. 3D shows the package 300d at an assembly stage where copper electroplating has been performed to form DSC pad 340 and SLI pads 341.

FIG. 3E shows the package 300e at an assembly stage where the DFR lamination 336 and the seed layer 334 have been removed. In embodiments, this may be performed through a DFR strip process, a seed etch, and a Pd strip process using potassium cyanide (KCN). The result is the exposure of the DSC pad 340 and SLI pads 341.

FIG. 3F shows the package 300f at an assembly stage where a surface finish 342 is applied to the exposed DSC pad 340 and SLI pads 341. In embodiments, the surface finish may be applied using an electroless technique, and may be an ENEPIG surface finish. In embodiments, the surface finish 342 may be applied using an electrolytic plating process. In embodiments, the actions described with respect to FIG. 3E and FIG. 3F may describe portions of a process to apply the surface finish 342.

FIG. 3G shows the package 300g at an assembly stage where laser drilling is performed to create cavities 344 to expose a surface of pads 324, 328, and to create cavities 346 to electrically couple with a component 345. Subsequent to the drilling, a protective film may be applied to cover the surface finish 342 on the backside and removed after a desmear process before a seed layer 348 is applied. Subsequently, a seed layer 348 may be applied.

FIG. 3H shows the package 300h at an assembly stage where a DFR 350 has been applied to both sides of the package 300h. Cavities 350a have been created in the DFR 350 created using either a laser drilling or a photo-lithographic technique.

FIG. 3I shows the package 300i at an assembly stage where electrolytic copper plating has been applied to form pads 352, 354.

FIG. 3J shows the package 300j at an assembly stage where the DFR 350 has been removed, and the seed layer 348 has been removed. In embodiments, the DFR 350 may be removed using a stripping process, and the seed layer 348 may be removed by an etching process.

FIG. 3K shows the package 300k at an assembly stage where solder resist 356 has been laminated on both sides of the package 300k. Subsequently, cavities 356a were created to expose FLI pads 352, 340 and SLI pads 341. In embodiments, the cavities may be created using a drilling technique or photolithography process.

FIG. 3L shows the package 3001 where an ultraviolet (UV) VIA drill may be used to drill cavities 358 into the solder resist 356 to create small SROs to access pads 354 connecting to device 345. As shown, the pads 352, 354 do not have any ENEPIG surface finish, which may add to the overall structure stability of the package 3001. Pads 340, 341 have an ENEPIG finish 342 to enhance the reliability of future electrical connections.

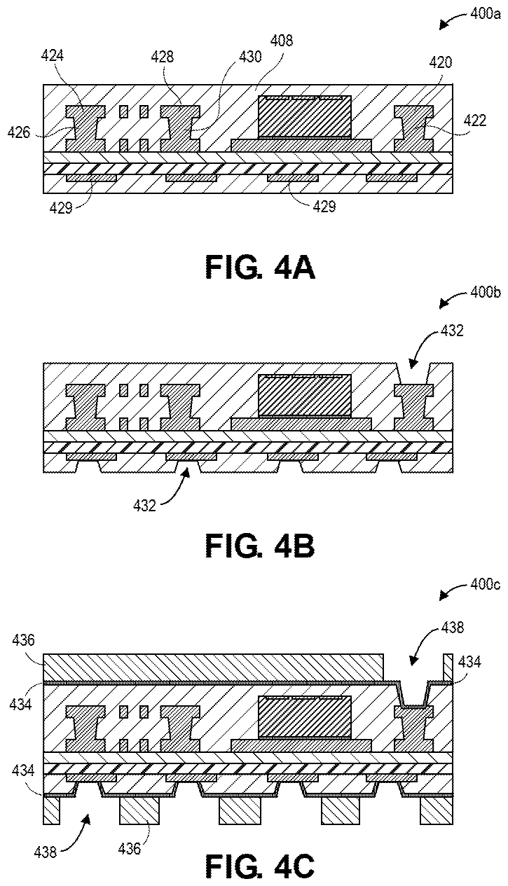

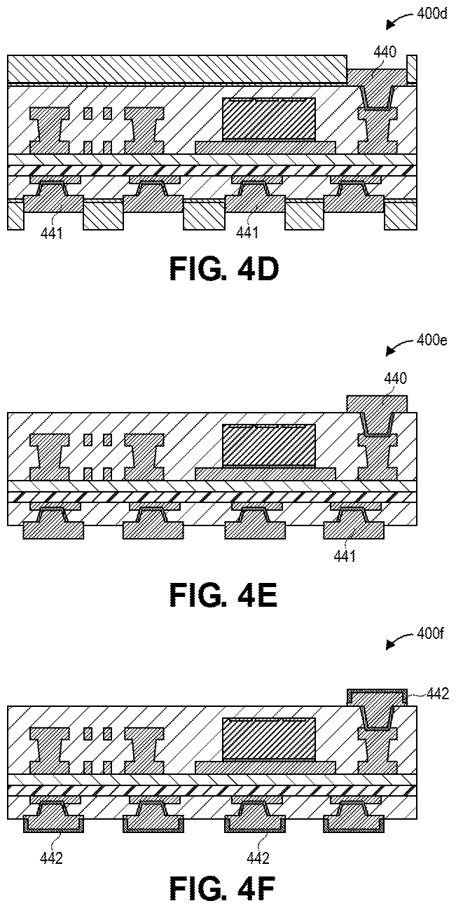

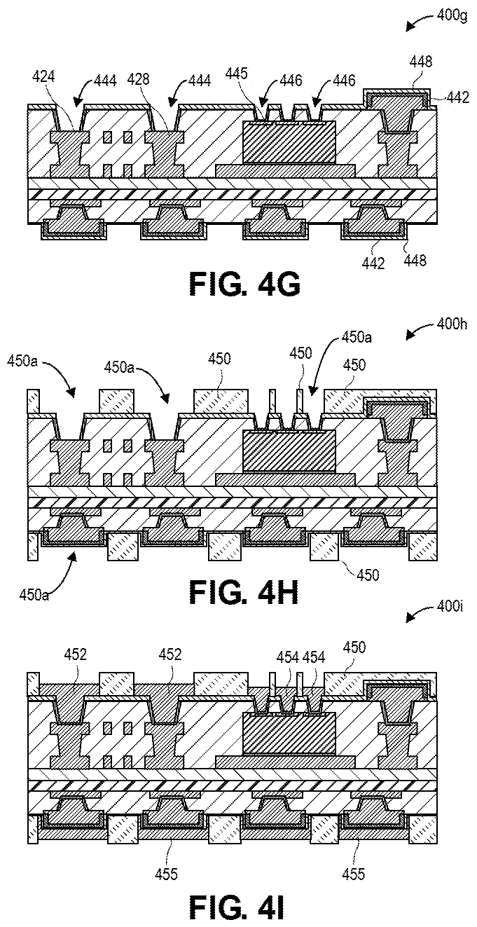

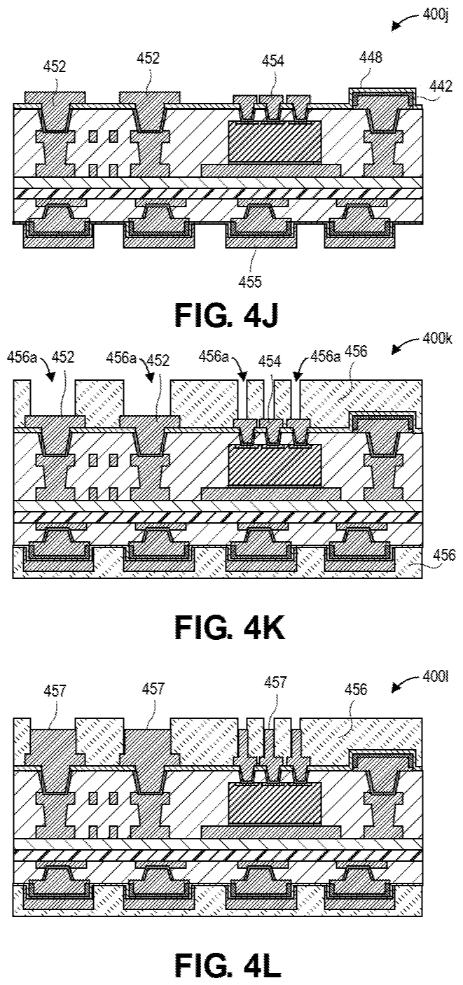

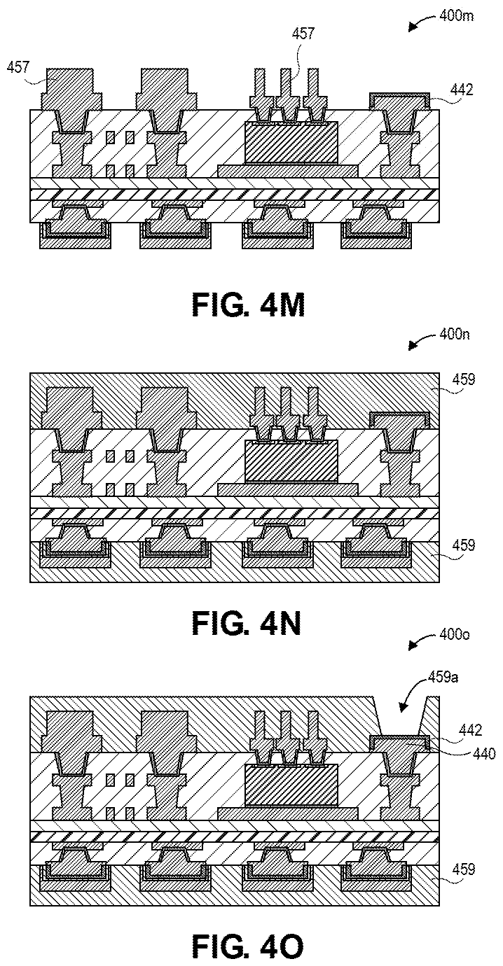

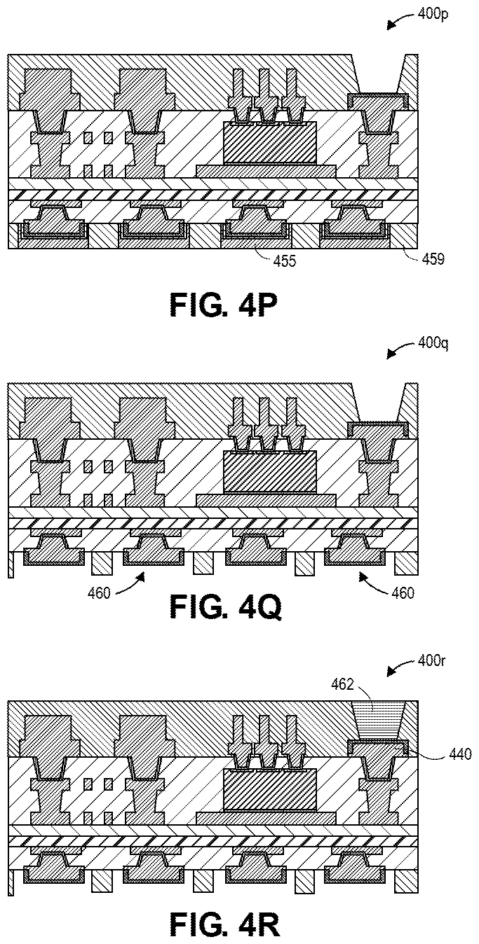

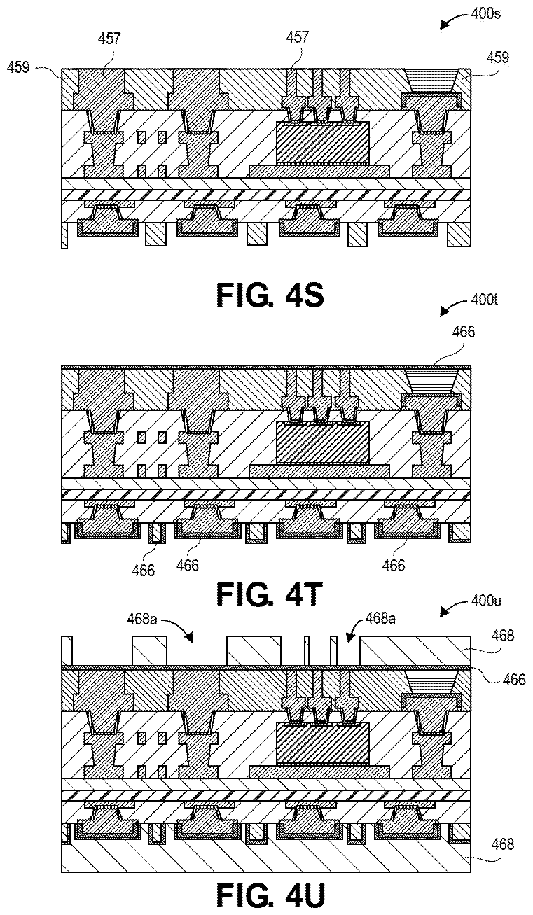

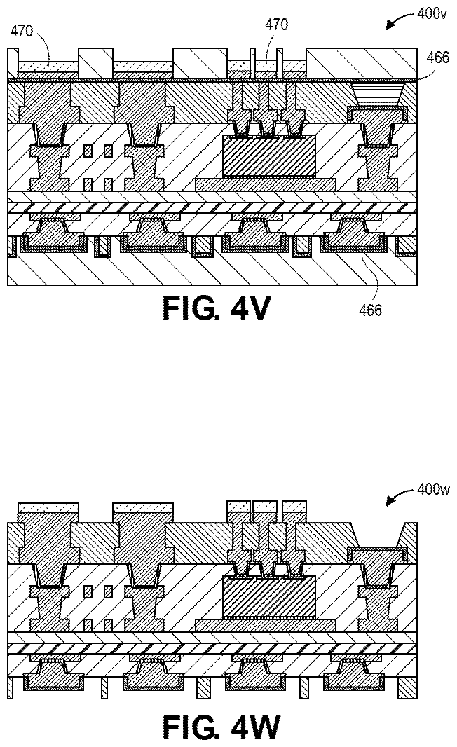

FIG. 4A-4W illustrate an example of a package assembly that includes a surface finish surrounding one or more pads at various stages of the manufacturing process that uses a LIV technique, in accordance with embodiments. FIGS. 4A-4W show an embodiment of a process for applying surface finish using a LIV based approach to form surface VIAs. In embodiments, selectivity in surface finish is achieved by splitting the surface layer formation into two parts where after the first pass of patterning is completed, the surface finish of the pads is achieved followed by second pass of the surface layer patterning.

FIG. 4A shows a package 400a as a substrate built up to an N-1 layer. The package 400a may include FLI pads 424, 428, 420 that are coupled respectively with VIAs 426, 430, 422. The package 400a may also include SLI pads 429, and may be enclosed by or partially enclosed by a molding 408.

FIG. 4B shows the package 400b at an assembly stage where a cavities 432 have been created into the package 400b to expose pads 420, 429. In embodiments, cavities 432 may be created using a VIA drill and DES on the front side and the backside of the package 400b.

FIG. 4C shows the package 400c at an assembly stage where a seed layer 434 is applied to both sides of the package 400c. This may be accomplished through an electroless plating process. Subsequently, a DFR lamination 436 may be applied. Openings 438 may subsequently be created through the DFR lamination 436 to expose portions of the seed layer 434.

FIG. 4D shows the package 400d at an assembly stage where copper electroplating has been performed to form DSC pad 440 and SLI pads 441.

FIG. 4E shows the package 400e at an assembly stage where the DFR lamination 436 and the seed layer 434 have been removed. In embodiments, this may be performed through a DFR strip process, a seed etch, and/or a Pd strip process using KCN as described above. The result is the exposure of the DSC pad 440 and SLI pads 441.

FIG. 4F shows the package 400f at an assembly stage where a surface finish 442 is applied to the exposed DSC pad 440 and SLI pads 441. In embodiments, the surface finish may be applied using an electroless technique, and may be an ENEPIG surface finish.

FIG. 4G shows the package 400g at an assembly stage where a laser drill is used performed to create cavities 444 to expose a surface of pads 424, 428, and to create cavities 446 to electrically couple with a component 445. During a subsequent drilling and desmear process, a protective film (not shown) may be applied and removed to cover the surface finish 442 on the backside. Subsequently, a seed layer 448 may be applied.

FIG. 4H shows the package 400h at an assembly stage where a DFR 450 has been applied to both sides of the package 400h, with cavities 450a created. In embodiments, the DFR 450 may be applied using a lamination technique.

FIG. 4I shows the package 400i at an assembly stage where a copper layer 452, 454 and 455 has been placed in the cavities 450a. In embodiments, the copper layer 452, 454 and 455 may be placed using a plating process.

FIG. 4J shows the package 400j at an assembly stage where the DFR 450 has been removed, with the seed layer 448 remaining. In embodiments, the DFR 450 may be stripped away.

FIG. 4K shows the package 400k at an assembly stage where another DFR layer 456 is applied on the front and the back side of package 400k. Subsequently, openings 456a have been drilled into the DFR 456 to expose at least a portion of pads 452, 454. In embodiments, the openings 456a may be created by a photolithography process.

FIG. 4L shows the package 4001 at an assembly stage where copper is placed in the openings 456a to produce VIAs 457. In embodiments, the placing of the VIAs 457 may be performed using a copper plating process.

FIG. 4M shows the package 400m at an assembly stage where the DFR 456 is stripped away, and the seed layer 448 is etched away.

FIG. 4N shows the package 400n at an assembly stage where a dielectric lamination 459 is applied to the front and back side of the package 400n. In embodiments, the dielectric lamination 459 may be used as a surface insulator.

FIG. 4O shows the package 400o at an assembly stage where a cavity 459a is formed within the dielectric lamination 459 to expose the pad 440 having the surface finish 442. In embodiments, the cavity 459a may be formed using a laser drill and desmear process, or may be formed through exposure if the dielectric lamination 459 is photo definable.

FIG. 4P shows the package 400p at an assembly stage where the package 400p backside 459 is planarized to expose the backside copper 455.

FIG. 4Q shows the package 400q at an assembly stage where the backside copper 455 is etched to create openings 460. In embodiments, the openings 460 create one or more SLI connection points.

FIG. 4R shows the package 400r at an assembly stage where a DFR 462 is filled in above the pad 440 to provide protection during subsequent processing.

FIG. 4S shows the package 400s at an assembly stage where the front side 459 is planarized to reveal copper VIAs 457.

FIG. 4T shows the package 400t at an assembly stage where a seed layer 466 is deposited on both sides of the package 400t.

FIG. 4U shows the package 400u at an assembly stage where a DFR 468 is laminated on both sides of the package 400u, and cavities 468a are created to expose a portion of the seed layer 466. In embodiments, the cavities 468a may be created using a photolithography process or drilling process.

FIG. 4V shows the package 400v at an assembly stage where a copper plating process is applied to the first side of the package 400v to create FLI copper plating 470 within cavities 468a. The copper plating 470 may be used to provide a stack up that may be required for FLI metallization, which may include a Cu/Ni/Sn stack up (not shown).

FIG. 4W shows the package 400w at an assembly stage where the DFR 468 is stripped away and the seed layer 466 and fill 462 are removed.

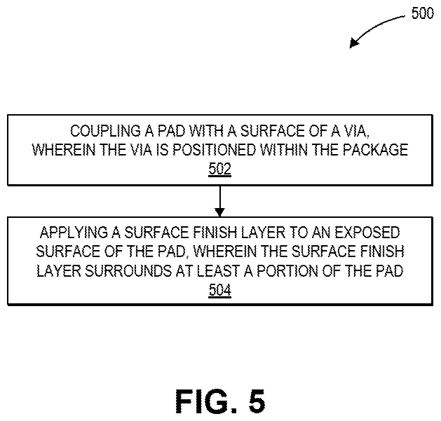

FIG. 5 illustrates an example of a process to surround a pad that is part of a package assembly with surface finish, in accordance with embodiments. Process 500 may be performed by one or more elements, techniques, or systems that may be found with respect to FIGS. 2-4W.

At block 502, the process may include coupling a pad with a surface of a VIA, wherein the VIA is positioned within the package. In embodiments, the package may be similar to package 200 of FIG. 2, packages 300a-300l of FIGS. 3A-3L respectively, packages 400a-400w of FIGS. 4A-4W respectively. In embodiments, the pad may be similar to pad 216 of FIG. 2, pads 324, 328, 320, 329 of FIGS. 3A-3L, or pads 424, 428, 420, 429 of FIGS. 4A-4W. In embodiments, the VIA may be similar to VIA 218 of FIG. 2, VIA 326, 330, 322 of FIGS. 3A-3L, or VIA 426, 430, 422 of FIGS. 4A-4W.

At block 504, the process may include applying a surface finish layer to an exposed surface of the pad, wherein the surface finish layer surrounds at least a portion of the pad. In embodiments, the surface finish layer may be a ENEPIG layer. In embodiments, the surface finish layer may be similar to surface finish layer 214 of FIG. 2, surface finish layer 342 of FIGS. 3F-3L, or surface finish layer 442 of FIGS. 4F-4W.

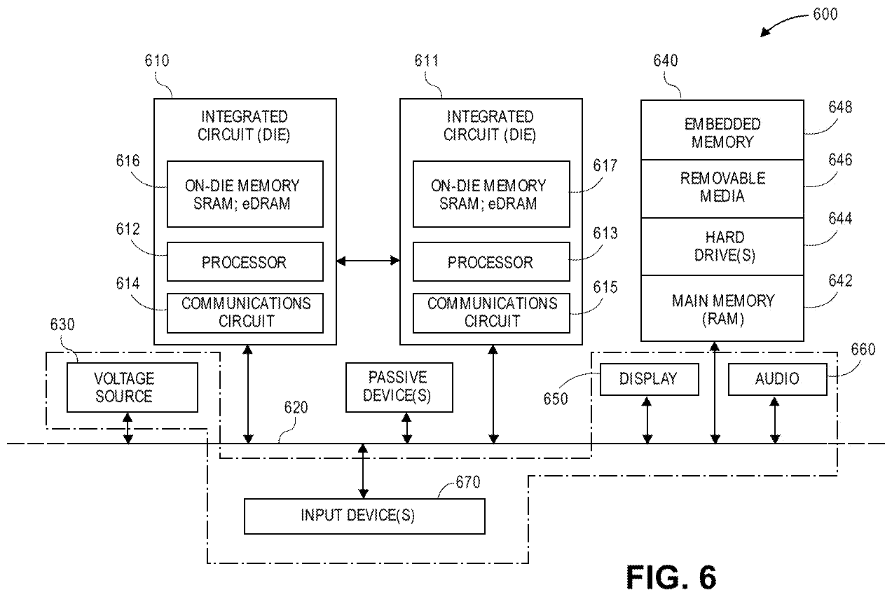

FIG. 6 schematically illustrates a computing device, in accordance with embodiments. The computer system 600 (also referred to as the electronic system 600) as depicted can embody surface finish surrounding a pad, according to any of the several disclosed embodiments and their equivalents as set forth in this disclosure. The computer system 600 may be a mobile device such as a netbook computer. The computer system 600 may be a mobile device such as a wireless smart phone. The computer system 600 may be a desktop computer. The computer system 600 may be a hand-held reader. The computer system 600 may be a server system. The computer system 600 may be a supercomputer or high-performance computing system.

In an embodiment, the electronic system 600 is a computer system that includes a system bus 620 to electrically couple the various components of the electronic system 600. The system bus 620 is a single bus or any combination of busses according to various embodiments. The electronic system 600 includes a voltage source 630 that provides power to the integrated circuit 610. In some embodiments, the voltage source 630 supplies current to the integrated circuit 610 through the system bus 620.

The integrated circuit 610 is electrically coupled to the system bus 620 and includes any circuit, or combination of circuits according to an embodiment. In an embodiment, the integrated circuit 610 includes a processor 612 that can be of any type. As used herein, the processor 612 may mean any type of circuit such as, but not limited to, a microprocessor, a microcontroller, a graphics processor, a digital signal processor, or another processor. In an embodiment, the processor 612 includes, or is coupled with, surface finish surrounding a pad, as disclosed herein. In an embodiment, SRAM embodiments are found in memory caches of the processor. Other types of circuits that can be included in the integrated circuit 610 are a custom circuit or an application-specific integrated circuit (ASIC), such as a communications circuit 614 for use in wireless devices such as cellular telephones, smart phones, pagers, portable computers, two-way radios, and similar electronic systems, or a communications circuit for servers. In an embodiment, the integrated circuit 610 includes on-die memory 616 such as static random-access memory (SRAM). In an embodiment, the integrated circuit 610 includes embedded on-die memory 616 such as embedded dynamic random-access memory (eDRAM).

In an embodiment, the integrated circuit 610 is complemented with a subsequent integrated circuit 611. Useful embodiments include a dual processor 613 and a dual communications circuit 615 and dual on-die memory 617 such as SRAM. In an embodiment, the dual integrated circuit 610 includes embedded on-die memory 617 such as eDRAM.

In an embodiment, the electronic system 600 also includes an external memory 640 that in turn may include one or more memory elements suitable to the particular application, such as a main memory 642 in the form of RAM, one or more hard drives 644, and/or one or more drives that handle removable media 646, such as diskettes, compact disks (CDs), digital variable disks (DVDs), flash memory drives, and other removable media known in the art. The external memory 640 may also be embedded memory 648 such as the first die in a die stack, according to an embodiment.

In an embodiment, the electronic system 600 also includes a display device 650, an audio output 660. In an embodiment, the electronic system 600 includes an input device such as a controller 670 that may be a keyboard, mouse, trackball, game controller, microphone, voice-recognition device, or any other input device that inputs information into the electronic system 600. In an embodiment, an input device 670 is a camera. In an embodiment, an input device 670 is a digital sound recorder. In an embodiment, an input device 670 is a camera and a digital sound recorder.

As shown herein, the integrated circuit 610 can be implemented in a number of different embodiments, including a package substrate having surface finish surrounding a pad, according to any of the several disclosed embodiments and their equivalents, an electronic system, a computer system, one or more methods of fabricating an integrated circuit, and one or more methods of fabricating an electronic assembly that includes a package substrate having surface finish surrounding a pad, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having surface finish surrounding a pad embodiments and their equivalents. A foundation substrate may be included, as represented by the dashed line of FIG. 6. Passive devices may also be included, as is also depicted in FIG. 6.

### EXAMPLES

The following paragraphs describe examples of various embodiments.

Example 1 includes a package comprising: a pad that has a first side and a second side opposite the first side; a VIA that has a first end and a second end, wherein the first end of the VIA is coupled with at least a portion of the first side of the pad; and a surface finish directly coupled with and surrounding a surface of the pad that excludes the at least the portion of the first side of the pad.

Example 2 includes the package of example 1, wherein the surface finish is an ENEPIG layer.

Example 3 includes the package of example 1, wherein the pad is a second level interconnect (SLI) pad or a die side capacitor (DSC) pad.

Example 4 includes the package of any one of examples 1-3, wherein the pad is a first pad and the VIA is a first VIA; and further comprising: a second pad that has a first side and a second side opposite the first side; and a second VIA that has a first end and a second end, wherein the first end of the second VIA is coupled with at least a portion of the first side of the second pad.

Example 5 includes the package of example 4, further comprising a second layer of material directly coupled with at least a portion of the second side of the second pad.

Example 6 includes the package of example 5, wherein the second layer of material is an ENEPIG layer.

Example 7 includes the package of example 4, wherein the first pad was created prior to the second pad.

Example 8 is a method, for creating a package, comprising: coupling a pad with a surface of a VIA, wherein the VIA is positioned within the package; and applying a surface finish layer to an exposed surface of the pad, wherein the surface finish layer surrounds at least a portion of the pad.

Example 9 includes the method of example 8, wherein coupling a pad with the surface of the VIA further includes: drilling a cavity through at least a portion of a layer of the package to expose the surface of the VIA; and filling at least the drilled cavity with a material to form the pad.

Example 10 includes the method of example 9, wherein filling at least the drilled cavity with the material further includes plating at least the drilled cavity with the material.

Example 11 includes the method of example 9, wherein the material is copper or a copper alloy.

Example 12 includes the method of example 9, wherein applying a surface finish layer further includes applying an ENEPIG layer.

Example 13 includes the method of example 8, wherein coupling a pad with the surface of the VIA further includes: applying a lithography process to create a buildup layer that includes a cavity proximate to the surface of the VIA; and filling at least the cavity with a material to form the pad.

Example 14 includes the method of example 13, further comprising removing the buildup layer.

Example 15 includes the method of example 8, wherein the pad is a first pad and the VIA is a first VIA; and further comprising after applying a surface finish layer to an exposed surface of the first pad: coupling a second pad with a surface of a second VIA, wherein the second VIA is positioned within the package.

Example 16 includes the method of any one of examples 8-15, wherein the package is a FLI.

Example 17 is a system, comprising: a circuit board; a package coupled with the circuit board, the package comprising: a pad that has a first side and a second side opposite the first side; a VIA that has a first end and a second end, wherein the first end of the VIA is coupled with at least a portion of the first side of the pad; and a layer of material directly coupled with and surrounding a surface of the pad that excludes the at least the portion of the first side of the pad.

Example 18 includes the system of example 17, wherein the layer of material is an ENEPIG layer.

Example 19 includes the system of any one of examples 17-18, wherein the pad is a first pad and the VIA is a first VIA; and the package further comprising: a second pad that has a first side and a second side opposite the first side; a second VIA that has a first end and a second end, wherein the first end of the second VIA is coupled with at least a portion of the first side of the second pad.

Example 20 includes the system of example 19, wherein the first pad or the second pad is a second level interconnect (SLI) pad or a die side capacitor (DSC) pad.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A package comprising:
a pad that has a first side and a second side opposite the first side;
a VIA that has a first end and a second end, wherein the first end of the VIA is coupled with at least a portion of the first side of the pad; and
a surface finish directly coupled with and surrounding a surface of the pad that excludes the at least the portion of the first side of the pad.

2. The package of claim 1, wherein the surface finish is an ENEPIG layer.

3. The package of claim 1, wherein the pad is a second level interconnect (SLI) pad or a die side capacitor (DSC) pad.

4. The package of claim 1, wherein the pad is a first pad and the VIA is a first VIA; and
further comprising:
a second pad that has a first side and a second side opposite the first side;
a second VIA that has a first end and a second end, wherein the first end of the second VIA is coupled with at least a portion of the first side of the second pad.

5. The package of claim 4, further comprising a second layer of material directly coupled with at least a portion of the second side of the second pad.

6. The package of claim 5, wherein the second layer of material is an ENEPIG layer. The package of claim 4, wherein the first pad was created prior to the second pad.

8. A method, for creating a package, comprising:
coupling a pad with a surface of a VIA, wherein the VIA is positioned within the package; and
applying a surface finish layer to an exposed surface of the pad, wherein the surface finish layer surrounds at least a portion of the pad.

9. The method of claim 8, wherein coupling a pad with the surface of the VIA further includes:
drilling a cavity through at least a portion of a layer of the package to expose the surface of the VIA; and
filling at least the drilled cavity with a material to form the pad.

10. The method of claim 9, wherein filling at least the drilled cavity with the material further includes plating at least the drilled cavity with the material.

11. The method of claim 9, wherein the material is copper or a copper alloy.

12. The method of claim 9, wherein applying a surface finish layer further includes applying an ENEPIG layer.

13. The method of claim 8, wherein coupling a pad with the surface of the VIA further includes:
applying a lithography process to create a buildup layer that includes a cavity proximate to the surface of the VIA; and
filling at least the cavity with a material to form the pad.

14. The method of claim 13, further comprising removing the buildup layer.

15. The method of claim 8, wherein the pad is a first pad and the VIA is a first VIA; and
further comprising after applying a surface finish layer to an exposed surface of the first pad: coupling a second pad with a surface of a second VIA, wherein the second VIA is positioned within the package.

16. The method of claim 8, wherein the package is a FLI.

17. A system, comprising:
a circuit board;
a package coupled with the circuit board, the package comprising:
a pad that has a first side and a second side opposite the first side;
a VIA that has a first end and a second end, wherein the first end of the VIA is coupled with at least a portion of the first side of the pad; and
a layer of material directly coupled with and surrounding a surface of the pad that excludes the at least the portion of the first side of the pad.

18. The system of claim 17, wherein the layer of material is an ENEPIG layer.

19. The system of claim 17, wherein the pad is a first pad and the VIA is a first VIA; and
the package further comprising:
a second pad that has a first side and a second side opposite the first side;
a second VIA that has a first end and a second end, wherein the first end of the second VIA is coupled with at least a portion of the first side of the second pad.

20. The system of claim 19, wherein the first pad or the second pad is a second level interconnect (SLI) pad or a die side capacitor (DSC) pad.
